(19) United States
(12) Patent Application Publication
(10) Pub. No.: US 2026/0016547 A1
(43) Pub. Date: Jan. 15, 2026

(54) METHOD FOR MONITORING THE CONTINUITY OF A PROTECTIVE EARTH OF A CHARGING SYSTEM FOR ELECTRIC VEHICLES AND CHARGING SYSTEM

(71) Applicant: Bender GmbH & Co. KG, Gruenberg (DE)

(72) Inventor: Lars Morich, Elz (DE)

(21) Appl. No.: 19/266,815

(22) Filed: Jul. 11, 2025

(30) Foreign Application Priority Data
Jul. 11, 2024 (DE) 10 2024 119 766.8

(51) Int. Cl. G01R 31/54; B60L 53/16; B60L 53/31; B60L 53/66

(52) U.S. Cl. CPC G01R 31/54; B60L 53/31; B60L 53/66; B60L 53/16

(57) ABSTRACT

A method for monitoring the continuity of a protective earth of a conductive charging system for electric vehicles configured according to standard IEC 61851-1 and having a charging station with having a CP generator for generating a CP control signal and a charging cable, which has the protective earth, active conductors, a CP signal conductor and a PP signal contact, the method including registering and evaluating a residual current flowing in the active conductors by an AC/DC sensitive residual-current monitoring module in combination with a measuring-current transformer. An interruption of the protective earth is determined in the residual current by registering and evaluating the CP control signal generated by the CP generator. A conductive charging system for electric vehicles based on standard IEC 61851-1 and implementing the method is also disclosed.

This application claims priority to German Patent Application No. 10 2024 119 766.8 filed on Jul. 11, 2024, the disclosure of which is incorporated herein by reference.

### TECHNICAL FIELD

The invention relates to a method for monitoring the continuity of a protective earth of a conductive charging system for electric vehicles, the charging system being configured according standard IEC 61851-1, and comprising a charging station having a CP generator (Control Pilot) for generating a CP control signal and a charging cable, which has the protective earth (PE), active conductors, a CP signal line and a PP signal contact (Proximity Pilot).

Furthermore, the invention relates to a conductive charging system for electric vehicles, the charging system being configured according to standard IEC 61851-1 for implementing the method according to the invention for monitoring the continuity of a protective earth.

### BACKGROUND

Standard IEC 61851-1 applies to charging systems for wired charging of electric vehicles and describes, among other things, the properties and operating conditions of the power supply equipment and the connection to the electric vehicle. In particular, the constant monitoring of the continuity of the protective earth to the electric vehicle is also prescribed.

Different charging modes are defined in this system standard. In conjunction with a permanently installed charging station, charging mode 3 is primarily used for single-phase and three-phase charging with alternating current. The control of the charging process as well as the safety functionality and the communication process between the charging station and the electric vehicle are integrated in the charging station and are preferably carried out there as functional units by a charge controller. The charging cable and the associated type 2 plug standardly have four current-carrying (active) conductors/contacts—three outer conductors L1, L2, L3 and the neutral conductor N—as well as the protective earth, the CP signal line and the PP signal contact.

Communication between the charging station and the electric vehicle takes place via the CP signal line. When the electric vehicle is connected, the CP control signal is generated by the CP generator in the charging station in the form of a square wave signal with a 1 kHz basic frequency and applied to the CP signal line. The maximum charging current available from the charging station is communicated to the electric vehicle via pulse width modulation (PWM signaling/coding) of the square wave signal.

The CP control signal sent from the charging station to the electric vehicle via the CP signal conductor is returned via the protective earth of the charging cable when the electric vehicle is connected. The charge controller in the charging station can therefore detect that an electric vehicle is connected to the charging station by measuring the voltage on the CP signal conductor to earth (protective earth), as a circuit is formed when the electric vehicle is connected and a current flows in this circuit, the magnitude of which is determined by the connection of different resistors on the vehicle side. As the protective earth serves as a return conductor for the CP control signal, the continuity of the protective earth can be monitored at the same time.

The CP control signal and thus the measured voltages determined on the charging station side at the CP signal conductor against the protective earth have different signal shapes with different amplitudes (constant or PWM-modulated signal curves), each curve being assigned a charge state (basic status) A to F. A measured, constant open-circuit voltage thus indicates that no electric vehicle is connected to the charging station (charge state A). If an electric vehicle is connected, the CP generator switches to charge status B with a PWM-modulated square wave signal and reduced amplitude as the CP control signal. When the electric vehicle is ready for charging, charge state C follows with further reduced amplitude of the PWM-modulated square wave signal. The other charge states D to F describe certain operating or error states. If the status changes to charge state A or charge state B, the electric vehicle is disconnected from the charging station within 100 ms.

However, the respective status or a status change cannot be reliably identified by the charging station if the return conductor for the CP control signal is a conductive connection other than the protective earth. In particular, if the protective earth is interrupted, it is not available as a return conductor for the CP control signal.

A method and a system for detecting a protective earth failure of a charging cable when a shield of another conductor is connected to both ends of the cable is disclosed in the state of the art in DE 10 2017 110 955 A1. The shielding is actively supplied electrically at at least one potential connection and a protective earth failure is detected if an electrical quantity occurring during the active supply exceeds at least one threshold value.

Furthermore, the disclosure US 2021/0048485 A1 shows a method for identifying a protective earth interruption during a charging process of an electric vehicle by evaluating the signal curve on the PP signal contact line.

### SUMMARY

The object of the present invention is therefore to design a further method for monitoring the continuity of the protective earth and a charging system implementing this method, by means of both of which an interruption of the protective earth can be detected.

This object is attained by registering and evaluating the CP control signal generated by the CP generator in the residual current to determine an interruption of the protective earth.

The basic idea of the method according to the invention is thus based on the fact that if the CP control signal cannot be returned via the protective earth due to a defect in the protective earth, a current driven by the CP generator can normally only flow back from the electric vehicle to the charging station via the active conductors. The residual current detected by the AC/DC-sensitive residual-current monitoring module in combination with a measuring-current transformer enclosing the active conductors is now evaluated to determine whether it contains a CP control signal generated by the CP generator as a residual current component. If a CP control signal is identified in the residual current, an interruption of the protective earth is considered to have occurred. With a continuous (intact) protective earth connection, no CP control signal will be detected in the residual current registered via the active conductors.

In a further advantageous embodiment, the residual-current monitoring module receives a signal via a transmission-status signal line when a PWM-modulated square signal generated in the CP generator has been sent.

The application of the 1 kHz square wave signal defined as a CP control signal in standard IEC 61851-1 to the CP signal conductor is communicated to the residual-current monitoring module via a transmission-status signal line. With this synchronization, the residual-current monitoring module knows in which period (with a defective protective earth) a CP control signal is to be expected, so that a 1 kHz interference signal generated by external influences and undesirably superimposed does not lead to a malfunction.

In addition to the transmission status (send/not send CP control signal) of the CP generator, the duty cycle of the PWM-modulated 1 kHz square wave signal is also communicated to the residual-current monitoring module via the transmission-status signal line in order to enable reliably identifying the CP control signal in the residual-current monitoring module by means of appropriate parameter settings.

Preferably, the CP control signal generated by the CP generator is identified and evaluated in the registered residual current by means of a software-based upgrade of the residual-current monitoring module.

The detection and evaluation of the CP control signal as part of the registered residual current is preferably carried out in the existing residual-current monitoring module. For this purpose, this is upgraded on a software basis, digital filter architectures being used, the parameterization of which is carried out using the transmitted PWM duty cycle.

Advantageously, an interruption of the protective earth determined by the residual-current monitoring module is signaled to a charge controller of the charging station by means of a PE status signal on a PE status line.

If the residual-current monitoring module identifies a CP control signal in the form of the 1 kHz square wave signal in the registered residual current and thus determines an interruption of the protective earth, this interruption of the protective earth is signaled to the charge controller of the charging station by means of a PE status signal on a PE status line.

The PE status line is evaluated in the charge controller for controlling the charging process.

If an interruption of the protective earth is determined and signaled by the PE status signal, the charge controller can activate a contactor to disconnect the electric vehicle and, if necessary, initiate further method steps.

Furthermore, the object of the invention is attained by a conductive charging system for electric vehicles, which is configured according to standard IEC 61851-1 and implements the method according to the invention.

The functional units of the conductive charging system according to the invention and described by the claimed structural features implement the corresponding method steps of the method according to the invention. Thus, the technical effects achieved with the method and the resulting advantages apply equally to the charging system.

In particular, the charging system has an AC/DC-sensitive residual-current monitoring module, which is configured to identify and evaluate the CP control signal generated by the CP generator in the registered residual current in order to determine an interruption of the protective earth.

The residual-current monitoring module, which is implemented using a software-based upgrade, is therefore able to detect the CP control signal in the form of the 1 kHz square wave signal on the active conductors.

This provides a further, particularly component-efficient option for monitoring the continuity of the protective earth.

### BRIEF DESCRIPTION OF THE DRAWINGS

Further advantageous design features are shown in the following description and the drawings, which illustrate a preferred embodiment of the invention by means of examples.

FIG. 1 shows a conductive charging system according to the invention having an intact protective earth.

FIG. 2 shows a conductive charging system according to the invention with an interruption of the protective earth.

### DETAILED DESCRIPTION

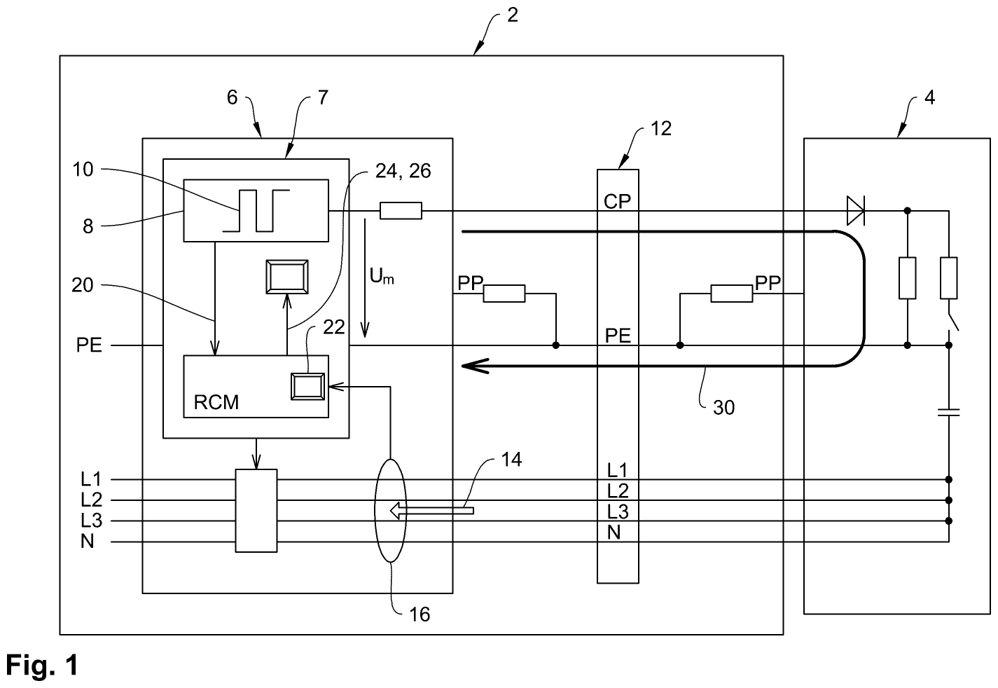

FIG. 1 shows a conductive charging system 2 for electric vehicles 4 having an intact protective earth PE, the conductive charging system 2 according to the invention being designed according to standard IEC 61851-1.

The charging system 2 comprises a charging station 6 and a charging cable 12 with active conductors L1, L2, L3, N and the protective earth PE to be monitored as well as a CP signal conductor CP and a PP signal contact as the plug contact of a standard type 2 plug.

The charging station 6 has a CP generator 8, which generates a CP control signal 10. The CP control signal 10 is applied to the CP signal conductor CP, the protective earth PE serving as the return conductor. When the electric vehicle 4 is connected, a circuit 30 is thus formed which runs via the CP signal conductor CP, a diode resistor branch in the electric vehicle 4 and the protective earth PE.

In the exemplary embodiment shown, the CP generator 8 and a residual-current monitoring module RCM are functional units of a charge controller 7. The residual-current monitoring module RCM is connected to a measuring-current transformer 16 enclosing the active conductors L1, L2, L3, N and registering a residual current 14.

The charging station 6 uses a voltage measurement (measurement voltage Uₘ) on the charging station side between the CP signal conductor CP and the protective earth PE to determine whether an electric vehicle 4 is connected. If no electric vehicle 4 is connected (charge state A), a DC voltage (open-circuit voltage) applied by the CP generator 8 is measured as the measurement voltage Uₘ.

If the electric vehicle 4 is connected, the circuit 30 is formed due to a resistor connected on the vehicle side, a drop in the measured voltage Uₘ at the CP signal conductor CP against the protective earth PE being identified by the charging station 6 (charge state B) and the CP generator then switching a PWM-modulated 1 kHz square wave signal to the CP signal conductor CP as a CP control signal 10.

If the electric vehicle 4 is ready for charging, it switches another (parallel) resistor between the CP signal conductor CP and the protective earth PE so that a corresponding voltage drop in the measured voltage Uₘ is detected by the charging station 6 and the charging current is enabled. The currently available charging current is communicated to the electric vehicle 4 by pulse width modulation of the 1 kHz square wave signal from the charging station 6.

A continuous, intact protective earth connection (protective earth PE) is therefore essential for controlling the charging process and for communication between the charging station 2 and electric vehicle 4, in addition to ensuring electrical safety.

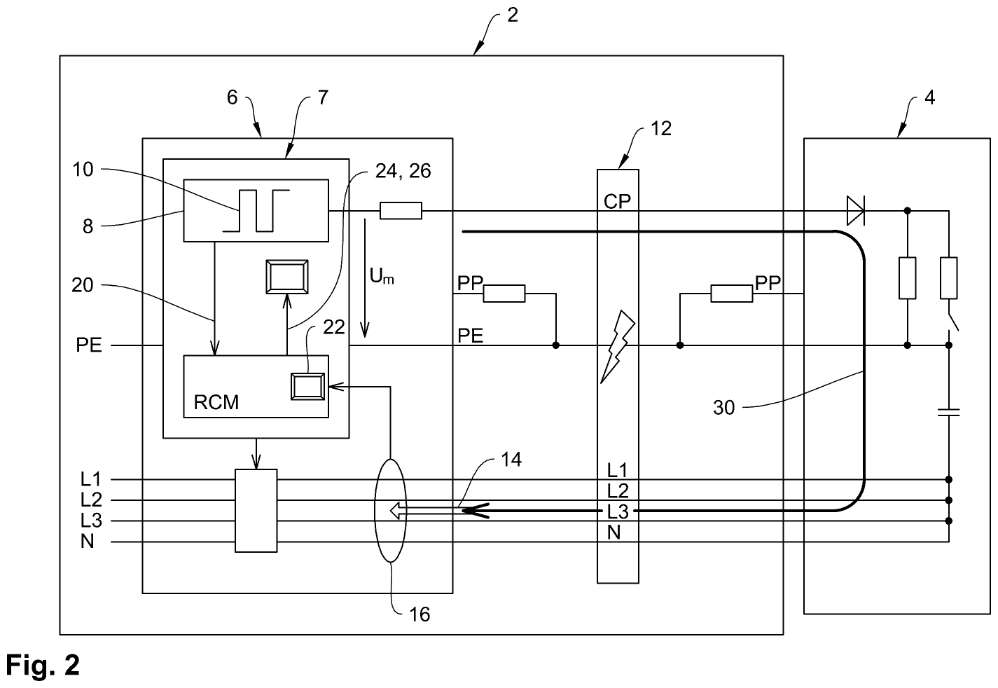

FIG. 2 shows a conductive charging system 2 for electric vehicles 4, the conductive charging system 2 according to the invention being designed according to standard IEC 61851-1 in the event of an interruption 18 of the protective earth PE.

In this case, the current caused by the CP control signal 10 cannot be returned via the protective earth PE. As a rule, the circuit 30 is then closed via the active conductors L1, L2, L3, N.

According to the invention, the residual-current monitoring module RCM is designed in such a manner that a residual-current curve corresponding to the CP control signal 10 can be identified and evaluated in the residual current 14.

For this purpose, the residual-current monitoring module RCM comprises a software-based upgrade 22, which detects the 1 kHz square wave signal by means of digital signal processing (filtering).

In order to signal to the residual-current monitoring module RCM when the CP control signal 10 is transmitted in the (signal) form of the 1 kHz square wave signal and is therefore to be expected on the active conductors L1, L2, L3, N when the protective earth PE is interrupted, the residual-current monitoring module RCM is synchronized with the CP generator 8 via a data interface with a transmission-status signal line 20. At the same time, the duty cycle of the PWM-modulated 1 kHz square wave signal is transmitted via the transmission-status signal line 20 for suitable adjustment of the software-based filter parameters.

An interruption 18 of the protective earth PE determined by the residual-current monitoring module RCM is signaled to the charge controller 7 of the charging station 6 by means of a PE status signal 24 via a data interface with a PE status line 26. The charge controller 7 is thus able to release the charging current or, if necessary, refuse to release it after evaluating the PE status signals 24.

1. A method for monitoring the continuity of a protective earth (PE) of a conductive charging system (2) for electric vehicles (4), the charging system (2) being configured according to standard IEC 61851-1 and comprising a charging station (6) having a CP generator (8) for generating a CP control signal (10) and a charging cable (12), which has the protective earth (PE), active conductors (N, L1, L2, L3), a CP signal conductor (CP) and a PP signal contact (PP), the method comprising the steps of: registering and evaluating a residual current (14) flowing in the active conductors (N, L1, L2, L3) by means of an AC/DC sensitive residual-current monitoring module (RCM) in combination with a measuring-current transformer (16), wherein an interruption (18) of the protective earth (PE) is determined in the residual current (14) by registering and evaluating the CP control signal (10) generated by the CP generator (8).

2. The method according to claim 1, wherein the residual-current monitoring module (RCM) receives a signal via a transmission-status signal line (20) when a PWM-modulated square signal generated in the CP generator (8) has been sent.

3. The method according to claim 1, wherein the CP control signal (10) generated by the CP generator (8) is identified and evaluated in the registered residual current (14) by means of a software-based upgrade (22) of the residual-current monitoring module (RCM).

4. The method according to claim 1, wherein an interruption (18) of the protective earth (PE) determined by the residual-current monitoring module (RCM) is signaled to a charge controller (7) of the charging station (6) by means of a PE status signal (24) on a PE status line (26).

5. The method according to claim 4, wherein the PE status line (24) is evaluated in the charge controller (7) for controlling the charging process.

6. A conductive charging system (2) for electric vehicles, which is configured according to standard IEC 61851-1 and for monitoring the continuity of a protective earth (PE), the charging system (2) comprising a charging station (6) having a CP generator (8) for generating a CP control signal (10) and a charging cable (12), which has the protective earth (PE), active conductors (N, L1, L2, L3), a CP signal line (CP) and a PP signal contact (PP), the conductive charging system (2) having an AC/DC-sensitive residual-current monitoring module (RCM), which registers and evaluates a residual current (14) flowing in the active conductors (N, L1, L2, L3) in the charging system (2) in combination with a measuring-current transformer (16), wherein the residual-current monitoring module (RCM) is configured for identifying and evaluating the CP control signal (10) generated by the CP generator (8) in the registered residual current (14) in order to determine an interruption (18) of the protective earth (PE).

7. The conductive charging system (2) for electric vehicles (4) according to claim 6, further including a transmission-status signal line (20) via which a signal is transmitted to the residual-current monitoring module (RCM) when the PWM-modulated square signal generated in the CP generator (8) has been transmitted.

8. The conductive charging system (2) for electric vehicles (4) according to claim 6, wherein the residual-current monitoring module (RCM) has a software-based upgrade (22) for identifying and evaluating the CP control signal (10) generated by the CP generator (8) in the registered residual current (14).

9. The conductive charging system (2) for electric vehicles (4) according to claim 6, further including a PE status line (26) via which an interruption (18) of the protective earth (PE) determined by the residual-current monitoring module (RCM) is transmitted to a charge controller (7) of the charging station (6) by means of a PE status signal (24).

10. The conductive charging system (2) for electric vehicles (4) according to claim 9, wherein the charge controller (7) is configured for evaluating the PE status signal (24) in order to control the charging process.
